(19) United States
(12) Patent Application Publication
(10) Pub. No.: US 2003/0030050 A1
(43) Pub. Date: Feb. 13, 2003

(54) Apparatus and method of inspecting semiconductor wafer

(76) Inventor: Byung-Kon Choi, Seoul (KR)

Correspondence Address: VOLPE AND KOENIG, P.C., SUITE 400, ONE PENN CENTER, 1617 JOHN F. KENNEDY BOULEVARD, PHILADELPHIA, PA, 19103, US

(21) Appl. No.: 10/239,797

(22) PCT Filed: Jan. 23, 2002
(86) PCT No.: PCT/KR02/00102

(30) Foreign Application Priority Data
Jan. 26, 2001 (KR) 2001/3761

(51) Int. Cl. H01L 47/00

(52) U.S. Cl. 257/4

(57) ABSTRACT

An apparatus and method of inspecting a removal state of a photoresist film coated on an edge portion of the semiconductor wafer in real time. The apparatus comprises a wafer supporting table, a semiconductor wafer horizontally mounted on the wafer supporting table, and at least one photographing unit, spaced apart from an edge of the semiconductor wafer, for photographing the edge of the wafer.

### TECHNICAL FIELD

The present invention relates to a semiconductor fabrication process, and more particularly, to an apparatus and method of inspecting a removal state of the photoresist film on a semiconductor wafer in real time after removing an edge portion of the photoresist film coated on an edge of the semiconductor wafer during a semiconductor fabrication process.

### BACKGROUND ART

Semiconductor chips are fabricated by performing many process steps. In order to fabricate a MOSFET (Metal Oxide Silicon Field Effect Transistor) in DRAM, silicon dioxide (SiO2) layer to be used as gate oxide is grown on a silicon substrate, polysilicon layer to be used as gate electrode is formed on the grown silicon dioxide layer, and word line, source electrode and drain electrode are formed by performing photolithography process, impurity implanting process and etching process.

Photolithography process is meant by to a process for transferring a pattern of a mask onto photoresist film coated on a workpiece by positioning a pattern mask over a semiconductor wafer, irradiating a light beam onto a photoresist film coated on the semiconductor wafer through the pattern mask. These photolithography processes are very important because they occupy a large portion of the semiconductor device fabrication process and affect directly on the yield. To this end, it is required to perform the photolithograpy process with accuracy and without faults.

FIG. 1 is a flow chart illustrating a general photolithography process.

Referring to FIG. 1, a wafer is processed with HMDS (Hexamethyldisilan) so that the adhesion of the wafer to a surface of an oxide film is improved. (11) After that, the wafer is cooled to a selected temperature (12), a raw material for the photoresist film is dispensed on the wafer and is uniformly coated by a centrifugal force generated by rotating the wafer. (13) Thereafter, the coated photoresist film is soft-baked at a temperature range of 70-90° C. for 0.5-30 minutes to evaporate the remaining solvent from the photoresist and simultaneously decrease an inner stress of the photoresist. (14) After the soft bake is completed, the wafer is cooled to a certain temperature, (15) and the EBR (Edge Bead Removal) process is performed to remove the photoresist coated on the outer edge of the wafer. (16) As the EBR process is ended, all processes before the exposure are completed. After that, the mask is aligned and the exposure process (17) and the developing process (19) are performed to form a pattern on the wafer.

Also, in order to substantially remove photoresist coated on the edge of the wafer, the WEE (Wafer Edge Exposure) process is selectively performed before or after the exposure process. (18) After the pattern is formed, a post-bake is performed to remove a residual solution of the developed photoresist and at the same time enhance the adhesion. (20) Photoresist is generally dispensed onto the rotating wafer in a liquid phase having the viscosity in a spin coater and is flowed outward by a centrifugal force generated by the rotation of the wafer, thus the photoresist is uniformly coated. Wafer is mounted on a rotating chuck having a disk shape. The diameter of the rotating chuck is generally smaller than that of the wafer. As the wafer is mounted on the chuck, the chuck firmly holds the rear surface of the wafer using a vacuum.

When exposing a wafer on which the photoresist is coated, using a mask, the exposure is performed at the chip region of the wafer. So, in case a positive photoresist which is separated into unit molecules and dissolved by irradiating a light is used, the photoresist of the edge portion is not exposed to the light unlike the chip region and remains unexposed after the developing process. In an ideal circumstance, the photoresist is coated in a uniform thickness and an overabundance of the photoresist raw solution is deviated from the edge portion of the wafer, whereby the overabundance solution is sprayed onto the wall of the spin coater. However, in real circumstance, a part of the overabundance solution is aggregated and remains as a shape of bead at the edge portion and the backside of the wafer.

FIG. 2 is a sectional view showing the photoresist 22 remaining at the edge portion and the photoresist bead 23 aggregated at the backside of the wafer 21.

These residuals have a problem in that when a wafer transferring unit such as the clamp transfers the wafer on which the photoresist is coated, the wafer transferring unit is directly in contact with the edge portion of the wafer. Therefore, when the coated photoresist remains at the edge portion of the wafer upon transferring the wafer, the photoresist of the edge portion may be stripped, which acts as foreign particles, resulting in the chip failure. To this end, after the photoresist is coated, a side rinse process or EBR (Edge Bead Removal) process is performed, in which a solvent is sprayed onto the residual photoresist to remove the same. Further, to firmly remove the residual photoresist when the coated photoresist is positive type, WEE (Wafer Edge Exposure) process in which the edge portion is separately exposed to remove the photoresist may be performed.

In the aforementioned WEE process, an exposing apparatus provided with the light source at an end portion reciprocates along a straight line path to expose the wafer flat zone and a rotation chuck rotates once or twice in a state where a optical cable is fixed to expose the edge of the ring type wafer continuously. After the exposure, a developing process is performed to remove the edge portion exposed to a developing solution.

FIG. 3 is a plan view of a wafer having an ideal shape in which the photoresist and the bead are removed. Here, the ideal shape is meant by the photoresist of the edge portion of the wafer being removed by a constant width “d”.

Then, if the photoresist is nonuniformly removed unlike that shown in FIG. 3, for example, if the wafer is fixed by the chuck or if the rotational center of the chuck is not aligned with the center of the wafer, the photoresist may be nonuniformly removed as shown in FIG. 4.

FIG. 4 is one example that the photoresist is nonuniformly removed. This removal failure is generated due to the nonuniformity in the rotation of the wafer. In other words, since the right side edge is overly stripped while the left side is insufficiently stripped, the photoresist is beside the center of the wafer toward the right side of the wafer, so that the width “d1” of the right side edge is smaller than that that of the left side edge. An unbalance phenomenon like this is generated by the instability of the spin coated itself or the instability on the process. At this time, chips placed at the right edge of the wafer may be unnecessarily etched due to such an exposure during a subsequent etch process or the photoresist of the left edge of the wafer acts as a source of particle as described previously, thereby lowering the process yield of the wafer. Thus, it is requested to inspect whether the photoresist of the edge portion of the wafer is normally removed but, in conventional art, this inspecting step is performed after the developing step is completed or the fabrication of the chip product is completed.

For example, an operator samples a lot in which the developing step is completed and inspects the sampled lot visually using an optical microscope, or confirms an occurrence of a failed chip in the edge portion of the wafer by performing an electrical test after the chips are completed.

These conventional inspecting methods, however, are not performed in real time and are performed manually after the delay of much time. Thus, although a failure is found after the developing step or in the electrical test, such finding timing is when many wafers having failed chips are already fabricated. Accordingly, the conventional inspecting method has high probability in that all wafers fabricated in the corresponding run are failed. In addition, it is difficult to precisely inspect the failure due to the uncertainty of the operator's manual inspection.

Accordingly, it is strongly requested to improve the conventional manual inspection.

### DISCLOSURE OF INVENTION

It is, therefore, an object of the present invention to provide an apparatus and method of deciding whether a process is normally performed by photographing an edge status of a semiconductor wafer and analyzing the photographed image depending on an analysis algorithm.

It is another object of the present invention to inspect a removal status of the photoresist coated on an edge portion of a semiconductor wafer fast and precisely in real time.

It is still another object of the present invention to enhance a semiconductor process yield by inspecting a removal status of the photoresist coated on an edge portion of a semiconductor wafer.

To achieve the above object, there is provided an apparatus for visually inspecting an edge status of a semiconductor wafer, comprising: a wafer supporting table: a semiconductor wafer horizontally mounted on the wafer supporting table; and at least one photographing unit spaced apart from an edge of the semiconductor wafer, for photographing an edge of the wafer.

According to another aspect of the present invention, there is provided a method of inspecting an edge of a semiconductor wafer, the method comprising the steps of: mounting the semiconductor wafer horizontally on a rotation chuck; rotating the semiconductor wafer by rotating the rotation chuck; photographing at least one edge image using a charge coupled device spaced apart from an edge of the semiconductor wafer, for photographing an edge of the wafer; analyzing the photographed image; and determining whether a process to be performed is normal or abnormal using the analyzed result.

### BRIEF DESCRIPTION OF DRAWINGS

The above objects, features and advantages of the present invention will become more apparent from the following detailed description when taken in conjunction with the accompanying drawings, in which:

FIG. 1 is a flow chart of a general photolithography process.

FIG. 2 is a sectional view showing a photoresist and a bead remaining at an edge of a wafer.

FIG. 3 is a plan view showing a state in which a photoresist and a bead remaining at an edge of a wafer are normally removed.

FIG. 4 is a plan view showing a state in which a photoresist and a bead remaining at an edge of a wafer are abnormally removed.

FIG. 5 is a perspective view of an apparatus for inspecting a semiconductor wafer according to an embodiment of the present invention.

FIG. 6 is a flow chart showing an algorithm that processes a photographed image into a data and analyzing the processed data.

FIG. 7 is a schematic diagram showing a photographed position shown on a semiconductor wafer.

### BEST MODE FOR CARRYING OUT THE INVENTION

A preferred embodiment of the present invention will now be described with reference to the accompanying drawings. In the following description, same drawing reference numerals are used for the same elements even in different drawings. The matters defined in the description such as a detailed construction and elements of a circuit are nothing but the ones provided to assist in a comprehensive understanding of the invention. Thus, it is apparent that the present invention can be carried out without those defined matters. Also, well-known functions or constructions are not described in detail since they would obscure the invention in unnecessary detail.

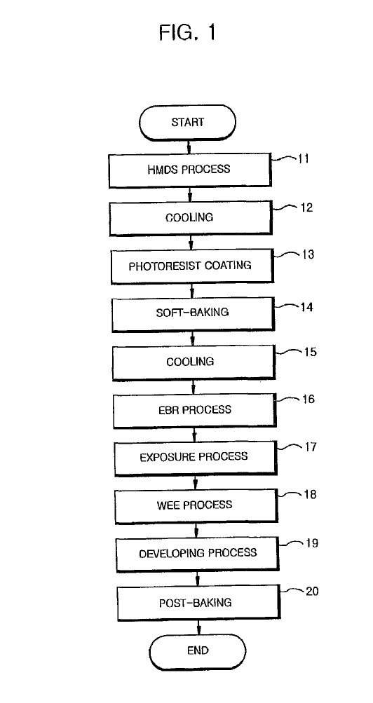

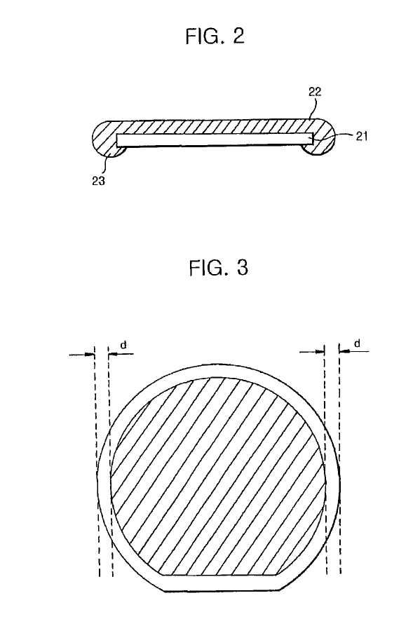

FIG. 5 is a perspective view of an apparatus of inspecting an edge status of a semiconductor wafer in accordance with one embodiment of the present invention. Referring to FIG. 1, a rotatable spin chuck 52 is disposed inside a wafer rotation track main body 51 and a semiconductor wafer 53 is mounted horizontally on the spin chuck 52. An apparatus of inspecting an edge status of the semiconductor wafer 53 includes: a photographing unit or a vision unit 54 for photographing an edge status of the semiconductor wafer 53 and transmitting a photographed edge image through a cable 56 into an analyzing unit 57 in which an image analysis software is installed; a supporting bar for supporting and transferring the vision unit 54.

As aforementioned, the present invention inspects a removal status of the photoresist immediately after the EBR or WEE is completed. Before or after the developing step, the wafer 53 in which the photoresist of its edge portion is removed is mounted on the spin chuck 52. As the spin chuck 52 rotates, the wafer 53 rotates too at a constant speed. At this time, the vision unit 54 placed over an edge of the wafer 53 photographs the edge portion of the wafer 53 momentarily. As the vision unit 54, a camera can be used. More preferably, an endoscope type of optical microscope using an optical fiber is used. The vision unit 54 also is interfaced with the analysis unit 57 to transmit the photographed image into the analysis unit 57.

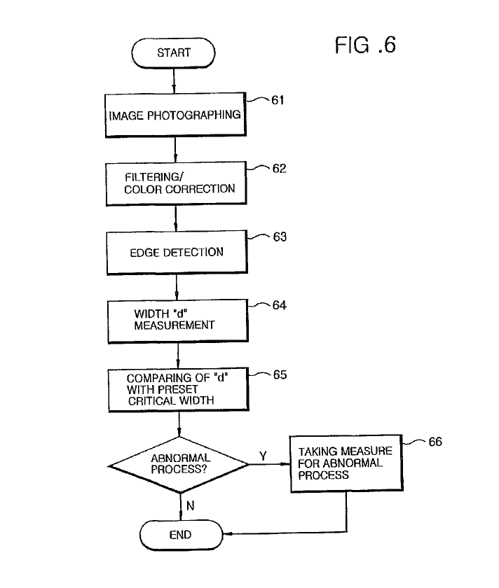

FIG. 6 is a flow chart illustrating an algorithm in which the photographed image is processed into an image data.

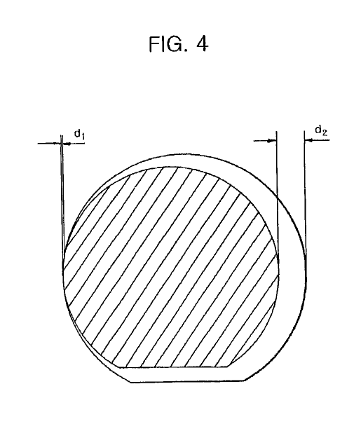

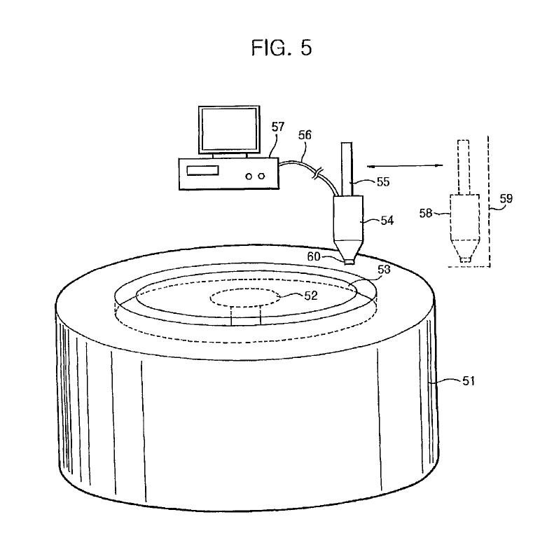

Referring to FIG. 6, as the vision unit 54 photographs the edge image of the wafer 53 (61) and transmits the photographed image into the analysis unit 57, the analysis unit 57 filters the transmitted image and correct a color to thereby perform a general image processing procedure. (62) After that, with a wafer image obtained by the image processing procedure, a wafer edge and a photoresist edge are discriminated. (63) At this time, the width “d” of the wafer edge in which the photoresist of the wafer edge is removed is also measured as shown in FIG. 3. (64) Thereafter, the measured width “d” is compared with a preset critical width (65).

After that, it is determined whether the photoresist coating process is normal or abnormal through the comparison. Depending on the determined results, measures are taken. For example, when the measured width “d” is larger than the critical value, it is determined that the process is abnormal, and thus the analysis unit 57 itself, or a control unit connected to the analysis unit 57 takes a measure for the abnormal process. (66) One of the measures for the abnormal process generates an alarm to inform the operator that the process is failed, or automatically stops the production line. After that, a calibration for repairing a mechanical instability or a process failure which is one of reasons of the stopping of the production line is performed to thereby prevent many wafers having defects from being subject to subsequent processes.

Next, a method of analyzing the photographed image is described in more detail.

The end portion of the wafer and the end portion of the photoresist are discriminated from the photographed input image. The width between the end portion of the wafer and the end portion of the photoresist is then measured. It is determined whether the measured width is included within a preset critical value or an error value. Depending on the determination results, it is determined whether the process is normal or abnormal.

For example, when the width of the photoresist removed by the EBR or WEE process is 2 mm and the critical value is preset ±10%, if a width “d” analyzed from the photographed image is in a range of 1.9 mm˜2.1 mm, the process is determined to be normal while if the width “d” analyzed from the photographed image is not in the range of 1.9 mm˜2.1 mm, the process is determined to be abnormal. The critical value is freely controlled depending on the process condition and the precision degree.

According to the invention, it is possible to determine whether the process is normal or abnormal using only one photographed image. However, for more precise determination, at least two photographed images are preferably used.

When one photographed image is used, there is no need to rotate the wafer. In other words, it is possible to photograph an image of the wafer and photoresist in a status in which the wafer is stopped. However, use of one photographed image may not detect a failure by photographing only normal portions although a defect exists on the wafer. In order to prevent the occurrence of the problem, multiple edge images spaced apart with a predetermined angle should be photographed and analyzed. Thus, even if any one of the measured width values is found, the process is determined to be abnormal.

Multiple edge images can be photographed by various methods. As one method, the single fixed vision unit 54 is arranged over an edge portion of the wafer 53 as shown in FIG. 5 and it photographs several positions of the edge portion of the wafer. At this time, the wafer 53 is rotating at a constant. As another method, multiple vision units are arranged over edge portions of the wafer 53 and they photograph only respective corresponding edge portions in a status in which the wafer 53 is stopped or the wafer is slightly rotated. Also, when plural vision units are used, it is possible to photograph plural images with rotating the plural vision units in a state that the wafer 53 is stopped.

In the latter method, it is desirous to maintain an interval of the photographed time at a constant value such that a division photographing is possible. For example, in a case the single vision unit photographs the wafer six times per second wherein the wafer is rotated one time per second, the single vision unit photographs the wafer per an interval of 60 degrees. Therefore, although the photoresist coated on the wafer is deviate toward one side, such a status can be detected precisely within comparatively short time.

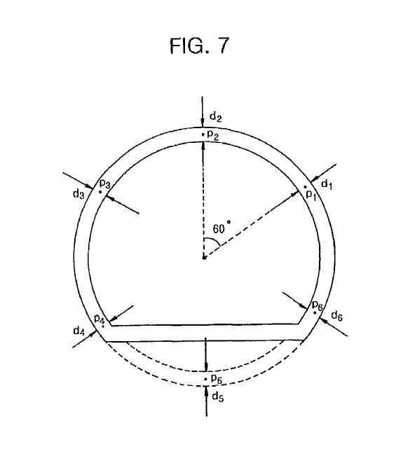

FIG. 7 is a schematic diagram showing an example that six places of P1-P6 on the wafer are photographed.

Referring to FIG. 7, intervals d1-d6 between the end portion of the wafer and the end portion of the photoresist in the selected six places are measured and a minimum value and a maximum value are obtained from the measured intervals d1-d6. If either the minimum value or the maximum value is not within a critical value, it is determined that the process is abnormal or failed. Here, since the image photographed at the place P5 corresponding to the flat zone of the wafer is the space not having a wafer image, an algorithm should be made such that the image is not contained as one of analysis data.

In a case the photoresist is errorneously removed, which is generated when the photoresist is deviated toward one side, a place corresponding to the maximum value and a place corresponding to the minimum value both are aligned on the same single diagonal line.

FIG. 7 is no more than one example. Therefore, considering a trade-off between the time spent in photographing of the image and the analysis of the photographed image and the precision, the number of photographed places should be properly computed. According to the inventor's experiment, it is preferable to photograph images of approximately 4-6 and analyze the photographed images.

In the apparatus of the present invention, the spin coater can be equally used as the track apparatus. In this case, only the vision unit is additionally installed at the conventional spin coater. In other words, there is no need to install another units except the vision unit. Then, when the spin coater is used, since the lens surface of the vision unit can be contaminated by a photoresist raw solution and other contamination sources, it is selectively requested to install a preventive unit of such a contamination additionally.

As an example of such the preventive unit, there is a shutter 60 as shown in FIG. 5. The shutter 60 is installed at the front of the lens of the vision unit 54. The shutter 60 is closed except the photographing period such that it is exposed to the external environment.

As another example, there is a method of moving the vision unit 54 whenever necessary. In more detail, referring to FIG. 5, the vision unit 54 is positioned at the photographing place only when photographing the image. And, as the photographing is completed, the vision unit 54 is moved to a distant place from the spin coater using the supporting bar 55 or is transferred into a protective housing 59 to isolate the vision unit 54 from the contamination source.

The vision unit 54 can be horizontally moved as shown in FIG. 5, or can be vertically moved over the track such that it is isolated from the contamination source.

### INDUSTRIAL APPLICABILITY

As described previously, the present invention is provided with an automatic vision unit capable of inspecting a removal status of the photoresist coated on the wafer in real time, thus preventing the delay of the inspection time, occurrence of failed wafers due to the delay and the lowering of the production yield.

In addition, the invention employs an automatic inspection method using hardware and software without using the conventional manual inspection, thereby enhancing the reliability in the inspection.

Moreover, the invention does not need to add many new elements except the vision unit and a few, thereby decreasing the installing costs.

While the invention has been shown and described with reference to certain preferred embodiments thereof, it will be understood by those skilled in the art that various changes in form and details may be made therein without departing from the spirit and scope of the invention as defined by the appended claims.

1. An apparatus for visually inspecting an edge state of a semiconductor wafer, comprising:
a wafer supporting table:
a semiconductor wafer horizontally mounted on the wafer supporting table; and
at least one photographing unit, spaced apart from an edge of the semiconductor wafer, for photographing the the edge of the wafer.

2. The apparatus of claim 1, wherein the wafer supporting table is rotatable.

3. The apparatus of claim 2, wherein the rotatable wafer supporting table is a rotation chuck of a photoresist coating apparatus.

4. The apparatus of any one of claims 1 to 3, wherein the photographing unit is an optic fiber type optical microscope.

5. The apparatus of any one of claims 1 to 3, wherein the photographing unit comprises a shutter provided on a front surface of the photographing unit.

6. The apparatus of any one of claims 1 to 3, wherein the photographing unit is movable from the edge of the semiconductor wafer by movement of the wafer supporting table.

7. The apparatus of any one of claims 1 to 3, wherein the photographing unit is movable into a protecting housing for protecting the front surface of the photographing unit from a contamination source by the wafer supporting table.

8. A method of inspecting an edge of a semiconductor wafer, the method comprising the steps of:
mounting the semiconductor wafer horizontally on a rotation chuck;
rotating the semiconductor wafer by rotating the rotation chuck;
photographing at least one edge image of the semiconductor wager using a photographing unit, which is spaced apart from the edge of the semiconductor wafer, for photographing the edge of the wafer;
analyzing the photographed image; and
determining whether a process to be performed is normal or abnormal according to a result of analysis.

9. The method of claim 8, wherein the analyzing step analyzes whether a photoresist on the semiconductor wafer is uniformly removed.

10. A method of inspecting a removal state of a photoresist film coated on an edge of a semiconductor wafer, the method comprising the steps of:
removing an edge portion of the photoresist film coated on the semiconductor wafer with a uniform width from the edge of the semiconductor wafer;
photographing an image of at least one edge portion of the semiconductor wafer from which the photoresist film is removed;
obtaining a distance difference between the edge of the semiconductor wafer and the edge of the remaining photoresist film from the photographed image;
comparing the obtained distance difference with a preset critical value; and
determining a process to be normal when the distance difference is within a predetermined range, and the process to be abnormal when the distance difference exceeds the predetermined range.

11. The method of claim 10, wherein the predetermined range is defined by a minimum value and a maximum value.
